(19) United States
(12) Patent Application Publication
(10) Pub. No.: US 2004/0147123 A1
(43) Pub. Date: Jul. 29, 2004

(54) Chemical mechanical polishing slurry for ruthenium titanium nitride and polishing process using the same

(75) Inventors: Jae Hong Kim, Kyoungki-do (KR); Sang Ick Lee, Kyoungki-do (KR)

Correspondence Address: MARSHALL, GERSTEIN & BORUN LLP, 6300 SEARS TOWER, 233 S. WACKER DRIVE, CHICAGO, IL, 60606, US

(73) Assignee: Hynix Semiconductor Inc.

(21) Appl. No.: 10/719,135

(22) Filed: Nov. 21, 2003

Related U.S. Application Data
(62) Division of application No. 10/096,266, filed on Mar. 12, 2002, now abandoned.

(30) Foreign Application Priority Data
Jun. 29, 2001 (KR) 2001-38114

(51) Int. Cl. H01L 21/302; H01L 21/461

(52) U.S. Cl. 438/689

(57) ABSTRACT

A CMP slurry for ruthenium titanium nitride and a polishing process using the same. In a process technology below 0.1 μm, when a capacitor using a (Ba₁₋ₓSrₓ)TiO₃ film as a dielectric film is fabricated, the slurry is used to polish a ruthenium titanium nitride film deposited as a barrier film according to a CMP process. The CMP process is performed by using the slurry, to improve a polishing speed of ruthenium titanium nitride under a low polishing pressure. In addition, the CMP process is performed according to an one-step process by using one kind of slurry. As a result, defects on an insulating film are reduced and a polishing property is improved, thereby simplifying the CMP process.

### BACKGROUND

1. Technical Field

A chemical mechanical polishing (abbreviated as ‘CMP’) slurry for ruthenium titanium nitride (abbreviated as ‘RTN’), and a polishing process using the same are disclosed. In particular, a slurry is disclosed that is used when a RTN film deposited as a barrier film is polished according to a CMP process in forming a capacitor using a (Ba₁₋ₓSrₓ)TiO₃ (abbreviated as ‘BST’) film as a dielectric film in a process technology below 0.1 μm. A polishing process using the same is also disclosed.

2. Description of the Related Art

RTN is a precious material which has excellent mechanical and chemical properties and which is essential to form a high performance capacitor. RTN is used as a barrier film. According to the present invention, a CMP process is employed to polish RTN.

Here, the CMP process is a purification process mostly used for a semiconductor wafer manufacturing process over 64M requiring high accuracy, and the slurry is a chemicals for planarizing various insulating films on a silicon substrate. In general, the slurry consists of a solvent, a compound and an abrasive. Mostly, a surfactant is added in a small volume to improve a CMP property.

A compound and an abrasive are dependent upon a kind of a film to be polished. For example, an alkali solution such as KOH or NH₄OH is used as a compound for polishing an oxide film, and SiO₂ is used as an abrasive for polishing the oxide film, and an oxidizer such as hydrogen peroxide is used as a compound for polishing a metal film, H₂SO₄, HNO₃ or HCl is added in a small volume to adjust the slurry to acidity, and Al₂O₃ is used as an abrasive for polishing the metal film.

The CMP process is performed by combining a chemical reaction and a mechanical reaction. The chemical reaction implies a chemical reaction between a compound contained in the slurry and a film. In the mechanical reaction, a force applied by a polishing device is transmitted to the abrasive in the slurry, and the film receiving the chemical reaction is mechanically separated by the abrasive.

That is, in the CMP process, a rotating polishing pad and a substrate are directly pressure-contacted, and the polishing slurry is provided to an interface thereof. Thus, the surface of the substrate is mechanically chemically polished and planarized by the polishing pad coated with the slurry. Accordingly, a polishing speed and a defect and erosion of the polished surface vary with a composition of the slurry.

An appropriate slurry is not provided in polishing RTN according to the CMP process, and thus a slurry for tungsten or aluminum is employed. In this case, the polishing speed of RTN is very low, and thus the CMP process is performed for a long time under a high polishing pressure. Therefore, scratches and impurities are seriously generated on an insulating film.

And because RTN must be polished for a long time under a high polishing pressure, dishing which is polished more than the peripheral insulating film and erosion are generated on RTN adjacent to the insulating film, which deteriorate the properties of the device.

It will now be explained in detail with reference to the accompanying drawings.

FIG. 1 is a cross-sectional view illustrating a semiconductor device where RTN is deposited as a barrier film. A gate oxide film 2, a gate electrode 3 and a mask insulating film 4 are formed on a semiconductor substrate 1. An oxide film spacer 5 is formed at the side walls of the resultant structure. An interlayer insulating film is formed over the resultant structure. A presumed capacitor contact region is removed according to a photolithography process, thereby forming a interlayer insulating film pattern 6.

Thereafter, a stacked layer of polysilicon 7 and buffer film 8 fills up the contact hole as a contact plug and a RTN thin film 9 is formed on the whole surface of the resultant structure. A RTN thin film 9 is patterned and planarized according to the CMP process, thereby forming a barrier film.

FIG. 2 is a cross-sectional view in a state where the CMP process is performed on the RTN thin film 9 of FIG. 1 by using the general slurry.

The general conditions of the CMP process include a polishing pressure of 4 to 7 psi, a table revolution number of 80 to 100 rpm by a rotary type system, and a table movement speed of 600 to 700 ft/min by a linear type system.

However, the polishing speed of RTN is very low under the general conditions, and thus the CMP process is not successfully performed. So as to increase the polishing speed of RTN, the CMP process should be performed for an extended period of time, increasing a supply amount of slurry and a polishing pressure.

As a result, as shown in FIG. 2, scratches 10 are generated on the interlayer insulating film pattern 6 due to the high polishing pressure, impurities such as slurry residuals or particles 11 remain thereon, the RTN thin film 9 is polished more than the interlayer insulating film from a time of exposing the interlayer insulating film to cause a dishing phenomenon, and the peripheral interlayer insulating film is seriously eroded. Moreover, a slurry for the interlayer insulating film is required to remove the scratches 10 and the particles 11 generated after the CMP process of the RTN thin film.

That is, the RTN thin film 9 is polished in a first step, and the surface of the interlayer insulating film pattern 6 is slightly polished by using a specific slurry in a second step, thereby preventing generation of the particles 11.

### SUMMARY OF THE DISCLOSURE

Accordingly, a CMP slurry and a CMP process using the same are disclosed which can improve a polishing speed of RTN under a low polishing pressure and polish RTN according to an one-step process by using one kind of slurry.

In addition, a method for manufacturing a semiconductor device according to a CMP process using a slurry, and a semiconductor device manufactured according to the method are also disclosed.

More specifically, a CMP slurry for RTN, containing ceric ammonium nitrate [(NH₄)₂Ce (NO₃)₆], a CMP process using the same, a method for manufacturing a semiconductor device according to the CMP process using the slurry, and a semiconductor device manufactured according to the method are disclosed.

### BRIEF DESCRIPTION OF THE DRAWINGS

The disclosed slurries, processes, methods and devices will be better understood with reference to the accompanying drawings which are given only by way of illustration and thus are not limitative, wherein:

FIG. 1 is a cross-sectional view illustrating a semiconductor device where a RTN is deposited as a barrier film;

FIG. 2 is a cross-sectional view illustrating a semiconductor device where a RTN is patterned by using a known slurry; and

FIG. 3 is a cross-sectional view illustrating a semiconductor device where a RTN is patterned by using a disclosed slurry.

### DETAILED DESCRIPTION OF THE PRESENTLY PREFERRED EMBODIMENTS

First of all, a disclosed CMP slurry for RTN contains ceric ammonium nitrate [(NH₄)₂Ce(NO₃)₆]. The CMP slurry for RTN comprises distilled water, nitric acid (HNO₃), ceric ammonium nitrate and an abrasive. Preferably, HNO₃ is used in an amount ranging from about 1 to about 10% by weight of the slurry, ceric ammonium nitrate is used in an amount ranging from about 1 to about 10% by weight of the slurry, and the abrasive is used in an amount ranging from about 1 to about 5% by weight of the slurry. Here, HNO₃ and ceric ammonium nitrate are used in an amount ranging from about 1 to about 10% by weight of the slurry, thereby stabilizing and easily handling the slurry.

HNO₃ maintains pH of the slurry ranging from about 1 to about 7, preferably from about 1 to about 3 for strong acidity. H₂SO₄, HCl or H₃PO₄ may be used instead of HNO₃. However, HNO₃ is most efficient.

Ceric ammonium nitrate serves as an oxidizer for extracting electrons from ruthenium atoms. The more HNO₃ and ceric ammonium nitrate are used, the more the polishing speed of RTN can be increased under the identical pressure.

In more detail, the slurry containing about 2 wt % of HNO₃ and about 2 wt % of ceric ammonium nitrate has a polishing speed of about 450 Å/min under a polishing pressure of about 1 psi; the slurry containing about 2 wt % of HNO₃ and about 6 wt % of ceric ammonium nitrate has a polishing speed of about 700 Å/min under a polishing pressure of about 1 psi; the slurry containing about 2 wt % of HNO₃ and about 10 wt % of ceric ammonium nitrate has a polishing speed of about 950 Å/min under a polishing pressure of about 1 psi; the slurry containing about 6 wt % of HNO₃ and about 2 wt % of ceric ammonium nitrate has a polishing speed of about 550 Å/min under a polishing pressure of about 1 psi; and the slurry containing about 10 wt % of HNO₃ and about 2 wt % of ceric ammonium nitrate has a polishing speed of about 650 Å/min under a polishing pressure of about 1 psi.

As compared with the fact that the slurry containing about 2 wt % of HNO₃ and about 2 wt % of ceric ammonium nitrate has a polishing speed of about 1000 Å/min under a polishing pressure of about 4 psi, a polishing speed over 1000 Å/min even under a polishing pressure of about 1 psi can be obtained, by slightly increasing a content of HNO₃ and ceric ammonium nitrate.

However, when HNO₃ and ceric ammonium nitrate are used in an amount over 10% by weight of the slurry, the slurry is not stabilized, and a polishing property of a pattern wafer is deteriorated. Accordingly, the content of HNO₃ and ceric ammonium nitrate should be maintained to a range from about 1 to about 10% by weight of the slurry. In addition, the process should be performed under a low polishing pressure to improve the polishing property of the pattern wafer.

The abrasive is used to improve a mechanical operation of the slurry. In the present invention, CeO₂, ZrO₂ or Al₂O₃ having a grain size below 1 μm is used as the abrasive to minimize scratches.

Moreover, the slurry of the present invention contains a buffer solution to constantly maintain pH. Here, a mixture of organic acid and organic acid salt (1:1), preferably acetic acid and acetic acid salt (1:1) is used as the buffer solution.

As described above, the slurry of the present invention has strong acidity and reduces adhesion and density of ruthenium atoms by eroding or melting the surface of RTN. Therefore, a chemical property of RTN is so varied that RTN can be easily polished according to the CMP process.

That is, a mixture of HNO₃ and ceric ammonium nitrate added in the slurry increases an erosion and melting speed of RTN, to improve the polishing speed of RTN.

A method for preparing the CMP slurry for RTN in accordance with the present invention will now be described.

CeO₂, ZrO₂ or Al₂O₃ which is an abrasive is added to distilled water. Here, CeO₂, ZrO₂ or Al₂O₃ is added in a stirring speed of about 10000 rpm so that abrasive particles can not be agglomerated. Thereafter, HNO₃ and ceric ammonium nitrate are added thereto. The resulting mixture is stirred for about 30 minutes so that it can be completely mixed and stabilized. Therefore, the slurry of the present invention is prepared. Here, the abrasive is used in an amount ranging from about 1 to about 5% by weight of the slurry, and HNO₃ and ceric ammonium nitrate are used in an amount ranging from about 1 to about 10% by weight of the slurry.

In addition, another aspect of the present invention provides a CMP process using the CMP slurry for RTN.

A method for forming a RTN pattern includes:

(a) preparing a semiconductor substrate where a RTN thin film is formed; and

(b) patterning the RTN thin film according to the CMP process using the CMP slurry composition for RTN.

A method for forming the pattern of the RTN thin film will now be explained in more detail. The semiconductor substrate where the RTN thin film is formed is pressure-adhered to a polishing pad formed on a rotary table of a CMP system. The slurry is supplied to an interface of the polishing pad and the RTN thin film, thus performing the CMP process. In the CMP process, a polishing pressure ranges from about 1 to about 4 psi, a table revolution number of a rotary type system ranges from about 10 to about 80 rpm, and a table movement speed of a linear type system ranges from about 100 to about 600 ft/min in consideration of the polishing speed of RTN thin film and the polishing property of the interlayer insulating film and the pattern wafer. An end-point detector is used to sense a time point of exposing the interlayer insulating film.

The exposure time of the interlayer insulating film is sensed by using the end-point detector, and thus the RTN thin film is not more polished than the interlayer insulating film, thereby preventing the dishing phenomenon and the erosion of the peripheral interlayer insulating film.

A semiconductor device where RTN is patterned by using the CMP slurry for RTN will now be explained with reference to the accompanying drawings.

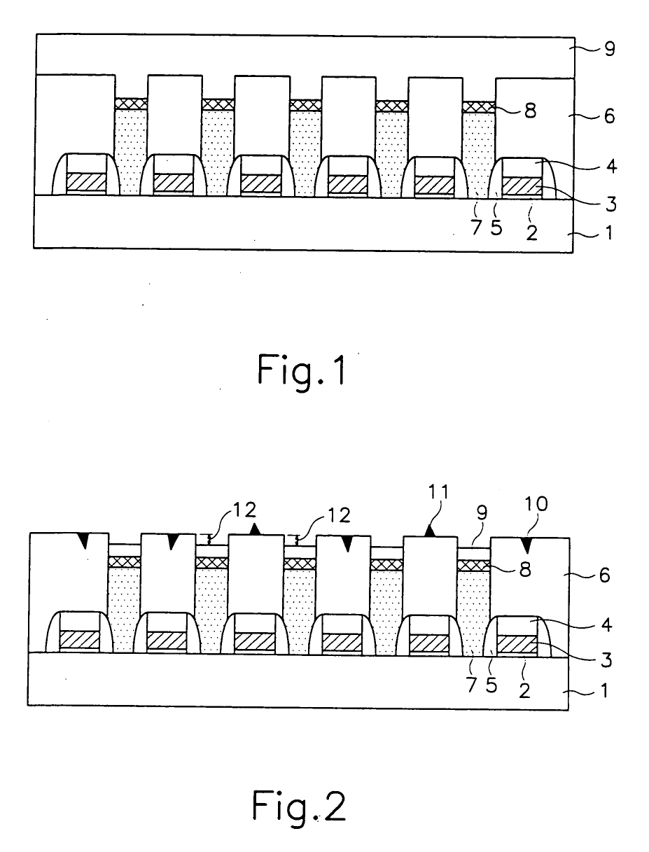

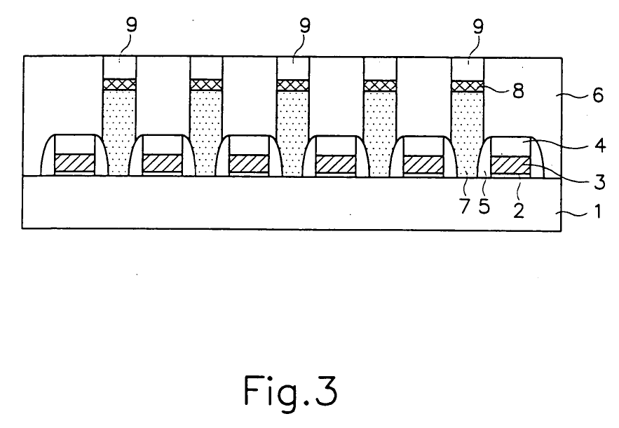

FIG. 3 is a cross-sectional view illustrating the semiconductor device where RTN is patterned by using the slurry of the present invention. The CMP process is performed on the RTN thin film 9 of FIG. 1, by employing the slurry of the present invention.

Referring to FIG. 3, when the CMP process is carried out in the process conditions of the present invention, defect generation on the interlayer insulating film pattern 6 and separation of the RTN thin film 9 are prevented to improve the polishing property.

That is, when the CMP process is performed under a minimum polishing pressure ranging from about 1 to about 4 psi which is generally allowable in any system, the RTN thin film 9 is closely adhered to the interlayer insulating film pattern 6, and defects and scratches are prevented.

In addition, when RTN thin film 9 is polished according to the CMP process using the slurry of the present invention, a slurry for the interlayer insulating film is not required, and RTN thin film 9 is polished according to an one-step process.

A method for manufacturing a semiconductor device includes patterning RTN by using the CMP slurry for RTN. The method for manufacturing the semiconductor device comprises:

(a) forming an interlayer insulating film on a semiconductor substrate 1 having a predetermined lower structure 2, 3, 4 and 5;

(b) patterning the interlayer insulating film to form an interlayer insulating film pattern 6 having a contact hole;

(c) filling up the contact hole with conducting material and performing over-etch to form a recess contact plug;

(d) depositing a RTN thin film 9 on the whole surface of the resultant structure; and

(e) forming a RTN thin film pattern on the recess contact plug by performing a CMP process.

As illustrated in FIG. 3, a gate oxide film 2, a gate electrode 3 and a mask insulating film 4 are formed on the semiconductor substrate 1 having the predetermined lower structure in step (a), an oxide film spacer 5 is formed at the sidewalls of the resultant structure and the conducting material of step (c) is polysilicon 8.

The method further comprises forming silicon nitride on the interlayer insulating film at the step (a) and forming a buffer film 8 between the contact plug and RTN film pattern. Preferably, the buffer film 8 is titanium silicide.

Moreover, in addition to the step (a) through (e), the following steps (f) through (h) can be included, thereby finishing fabrication of the capacitor:

(f) forming a sacrificial insulating film pattern which opens the contact plug;

(g) forming a lower electrode film on the resultant structure and performing a CMP process using the sacrificial insulating film pattern as an etch barrier to obtain a lower electrode pattern; and

(h) sequentially forming a dielectric film and an upper electrode on the resultant.

The lower electrode is a ruthenium film which is patterned by performing a CMP process using the slurry of this present invention.

A semiconductor device can be manufactured according to the method described above. The following examples are not intended to be limiting.

I. Preparation of Slurry

### EXAMPLE 1

CeO₂ having a grain size below 1 μm was added to 10 L of distilled water. Here, CeO₂ was added in a stirring speed of about 10000 rpm so that particles cannot be agglomerated. Thereafter, HNO₃ and ceric ammonium nitrate were added thereto. The resulting mixture was stirred for about 30 minutes so that it could be completely mixed and stabilized. Therefore, the slurry of the present invention was prepared. Here, CeO₂ was used in an amount of about 1% by weight of the slurry, and HNO₃ and ceric ammonium nitrate were used in an amount of about 2% by weight of the slurry, respectively.

### EXAMPLE 2

The procedure of Example 1 was repeated but using about 6 wt % of ceric ammonium nitrate, instead of using about 2 wt % of ceric ammonium nitrate.

### EXAMPLE 3

The procedure of Example 1 was repeated but using about 10 wt % of ceric ammonium nitrate, instead of using about 2 wt % of ceric ammonium nitrate.

### EXAMPLE 4

The procedure of Example 1 was repeated but using about 6 wt % of HNO₃, instead of using about 2 wt % of HNO₃.

### EXAMPLE 5

The procedure of Example 1 was repeated but using about 10 wt % of HNO₃, instead of using about 2 wt % of HNO₃.

II. CMP Process Using Slurry

### EXAMPLE 6

A table revolution number and a wafer revolution number were respectively set up to be about 20 rpm and about 80 rpm, by using a rotary type-system. Here, the CMP process was performed on the RTN thin film under a polishing pressure of about 1 psi by using the slurry prepared in Example 1 (polishing speed: about 450 Å/min).

An end-point detector is used to sense a time point of exposing the interlayer insulating film.

### EXAMPLE 7

The procedure of Example 6 was repeated but using the slurry prepared in Example 2, instead of using the slurry prepared in Example 1 (polishing speed: about 700 Å/min).

### EXAMPLE 8

The procedure of Example 6 was repeated but using the slurry prepared in Example 3, instead of using the slurry prepared in Example 1 (polishing speed: about 950 Å/min).

### EXAMPLE 9

The procedure of Example 6 was repeated but using the slurry prepared in Example 4, instead of using the slurry prepared in Example 1 (polishing speed: about 550 Å/min).

### EXAMPLE 10

The procedure of Example 6 was repeated but using the slurry prepared in Example 5, instead of using the slurry prepared in Example 1 (polishing speed: about 650 Å/min).

### EXAMPLE 11

A table movement speed and a wafer revolution number were respectively set up to be about 500 ft/min and about 20 rpm, by using a linear type system. Here, the CMP process was performed on the RTN thin film under a polishing pressure of about 1.5 psi by using the slurry prepared in Example 1 (polishing speed: about 500 Å/min).

### COMPARATIVE EXAMPLE 1

A table revolution number and a wafer revolution number were respectively set up to be about 20 rpm and about 80 rpm, by using a rotary type system. Here, the CMP process was performed on the RTN thin film under a polishing pressure of about 4 psi by using a slurry for tungsten (SSW2000 slurry of CABOT) (polishing speed about 350 Å/min).

### COMPARATIVE EXAMPLE 2

A table revolution number and a wafer revolution number were respectively set up to be about 20 rpm and about 80 rpm, by using a rotary type system. Here, the CMP process was performed on the RTN thin film under a polishing pressure of 4 psi by using a slurry for aluminum (EPA5680 slurry of CABOT) (polishing speed: about 500 Å/min).

HNO₃ and ceric ammonium nitrate are added to distilled water to prepare the slurry composition. However, other additives may be further added. Moreover, HNO₃ and ceric ammonium nitrate may be added to the general slurry composition.

As discussed earlier, the CMP process is performed by using the slurry containing ceric ammonium nitrate, thereby improving the polishing speed of RTN under a low polishing pressure. In addition, the CMP process is performed according to an one-step process by using one kind of slurry. As a result, defects on the insulating film are reduced and the polishing property is improved, thereby simplifying the CMP process.

Furthermore, a process margin and a process yield are improved due to the simplified CMP process.

What is claimed is:

1. A slurry used in a chemical mechanical polishing (CMP) process for ruthenium titanium nitride (RTN) thin film, the slurry comprising : ceric ammonium nitrate ((NH₄)₂Ce (NO₃)₆].

2. The slurry according to claim 1 further comprising an abrasive and an acid.

3. The slurry according to claim 2, wherein ceric ammonium nitrate is present in an amount ranging from about 1 to about 10% by weight of the slurry composition.

4. The slurry according to claim 2, wherein the acid is selected from the group consisting of HNO₃, H₂SO₄, HCl, H₃PO₄, and mixtures thereof.

5. The slurry according to claim 4, wherein HNO₃ is present in an amount ranging from about 1 to about 10% by weight of the slurry.

6. The slurry according to claim 2, wherein the abrasive is selected from the group consisting of CeO₂, ZrO₂, Al₂O₃ and mixtures thereof.

7. The slurry according to claim 2 or 6, wherein the size of the abrasive is below 1 μm.

8. The slurry composition according to claim 2 or 6, wherein the abrasive is present in an amount ranging from about 1 to about 5% by weight of the slurry.

9. The slurry composition according to claim 2, wherein pH of the slurry ranges from about 1 to about 7.

10. The slurry composition according to claim 9, wherein pH of the slurry ranges from about 1 to about 3.

11. The slurry according to claim 2, further comprising a buffer solution.

12. The slurry according to claim 11, wherein the buffer solution comprises a mixture of organic acid and organic acid salt.

13. The slurry according to claim 12, wherein the buffer solution comprises a mixture of acetic acid and acetic acid salt.

14. A method for forming a RTN pattern comprising:
(a) preparing a semiconductor substrate where a RTN thin film is formed; and
(b) patterning the RTN thin film according to a CMP process using a slurry of claim 2.

15. The method according to claim 14, wherein RTN thin film is a barrier film.

16. The method according to claim 14, wherein step (b) is performed under a polishing pressure ranging from about 1 to about 4 psi.

17. The method according to claim 14, wherein step (b) is performed by using a rotary type CMP system, and a table revolution number thereof ranges from about 10 to about 80 rpm.

18. The method according to claim 14, wherein step (b) is performed in a linear type CMP system where a table movement speed ranges from about 100 to about 600 ft/min.

19. A method for manufacturing a semiconductor device comprising:
(a) forming an interlayer insulating film on a semiconductor substrate having a predetermined lower structure;
(b) patterning the interlayer insulating film to form an interlayer insulating film pattern having a contact hole;
(c) filling the contact hole with conducting material and performing over-etch to form a recess contact plug;
(d) depositing a RTN thin film on the surface of the resultant structure; and
(e) forming a RTN thin film pattern on the recess contact plug by performing a CMP process using a CMP slurry of claim 2.

20. The method according to claim 19, wherein the conducting material of step (c) is polysilicon.

21. The method according to claim 19, further comprising the step of forming silicon nitride on the interlayer insulating film at the step (a).

22. The method according to claim 19, further comprising the step of forming a buffer film between the contact plug and RTN film pattern.

23. The method according to claim 22, wherein the buffer film is titanium silicide.

24. The method according to claim 19, further comprising:
(f) forming a sacrificial insulating film pattern which opens the contact plug;
(g) forming a lower electrode film on the resultant structure and performing a CMP process using the sacrificial insulating film pattern as an etch barrier to obtain a lower electrode pattern; and
(h) sequentially forming a dielectric film and an upper electrode on the resultant.

25. The method according to claim 24, wherein the lower electrode is a ruthenium film.

26. The method according to claim 24, wherein the dielectric film is a (Ba₁₋ₓSrₓ)TiO₃ film.

27. The method according to claim 25, wherein the ruthenium film is patterned by performing CMP process using the slurry of claim 2.

28. A semiconductor device manufactured according to a method of claim 19.
